(19) United States
(12) Patent Application Publication
(10) Pub. No.: US 2022/0235074 A1
(43) Pub. Date: Jul. 28, 2022

(54) METHOD FOR FORMING A METAL-ORGANIC FRAMEWORK

(71) Applicants: COMMISSARIAT A L'ENERGIE ATOMIQUE ET AUX ENERGIES ALTERNATIVES, Paris (FR); CENTRE NATIONAL DE LA RECHERCHE SCIENTIFIQUE, Paris (FR); ÉCOLE SUPÉRIEURE DE CHIMIE, PHYSIQUE, ELECTRONIQUE, Villeurbanne (FR); UNIVERSITE CLAUDE BERNARD LYON 1, Villeurbanne (FR)

(72) Inventors: Virginie PERROT, Grenoble cedex 9 (FR); Vincent JOUSSEAUME, Grenoble cedex 9 (FR); Elsje QUADRELLI, Lyon (FR); Arthur ROUSSEY, Grenoble cedex 09 (FR)

(21) Appl. No.: 17/586,673

(22) Filed: Jan. 27, 2022

(30) Foreign Application Priority Data
Jan. 28, 2021 (FR) 21/00820

(51) Int. Cl. C07F 3/06; C01B 37/00

(52) U.S. Cl. CPC C07F 3/06; C01B 37/00

(57) ABSTRACT

A method for forming a metal-organic framework comprising a step of providing a substrate; a single step of forming a single layer of metal oxide formed on the substrate said layer of metal oxide being transformed in whole or in part into metal-organic framework by successive implementation of a plurality of reaction cycles; each reaction cycle of the plurality of reaction cycles comprising: a treatment step with at least one ligand; a treatment step with at least one additive; the reaction cycles being implemented at least twice so as to form the metal-organic framework on the substrate.

### CROSS REFERENCE TO RELATED APPLICATIONS

This application claims priority under 35 U.S.C. § 119 to the following French Patent Application No. FR 21/00820, filed on Jan. 28, 2021, the entire contents of which are incorporated herein by reference thereto.

### TECHNICAL FIELD

The present invention concerns a method for forming a metal-organic framework on a substrate.

The invention also relates to a metal-organic framework obtained by such a method.

### BACKGROUND

The porous metal-organic frameworks, called MOF are crystalline hybrid materials created from organic molecules called ligands and inorganic molecules, such as metal ions salts, forming a structure in one, two or three dimensions. These materials, due to their regular structure, have a porosity whose pore diameter is in the range of one angstrom to a hundred angstrom with extremely high specific surface values and maximums reaching 7000 m²·g⁻¹.

These characteristics, coupled with their mechanical, thermal and/or chemical resistance, make them particularly attractive as adsorbent materials or sensitive layers to be integrated into devices for detecting or capturing gas or liquid.

The porous metal-organic frameworks are generally synthesized in the form of powder by solution methods, unfortunately their integration in devices, and in particular in devices of micrometric size, is difficult.

There is therefore a need to obtain a method for manufacturing porous metal-organic frameworks compatible with microelectronics standards.

### BRIEF SUMMARY

The present invention aims to respond to all or part of the problems presented above.

In particular, one object is to provide a solution that meets all or part of the following objectives:
to obtain a method making it possible to be compatible with microelectronics;
to obtain a metal-organic framework with acceptable structural properties.

This object can be achieved through the implementation of a method for forming a metal-organic framework comprising:
a step of supplying a substrate;
a single step of forming a single layer of metal oxide formed on the substrate, said layer of metal oxide being transformed in whole or in part into metal-organic framework by successive implementation of a plurality of reaction cycles P; each reaction cycle P of the plurality of reaction cycles comprising:

a treatment step with at least one ligand;

a treatment step with at least one additive;

the reaction cycles P being implemented at least twice so as to form the metal-organic framework on the substrate.

Some preferred but non-limiting aspects of this method are as follows.

In an implementation of the method, the reaction cycle P comprises a purge step P0 consisting of placing under vacuum and/or supplying inert gas; the purge step P0 being carried out before and/or after the treatment step with a ligand.

In an implementation of the method, the treatment step with an additive takes place at least in part during the treatment step with a ligand.

In an implementation of the method, the metal oxide is a zinc oxide, a cobalt oxide, a copper oxide, an iron oxide or an indium oxide.

In an implementation of the method, the reaction cycles P are repeated until the layer of metal oxide is completely transformed into metal-organic framework.

In an implementation of the method, the additive is water or an alcohol or a polyol or a combination of these additives or a reagent intended to form at least one of these additives during the reaction cycle P.

In an implementation of the method, the substrate and/or said ligand and/or said additive is maintained at a temperature comprised between 80° C. and 180° C. during the reaction cycle P.

In an implementation of the method, the treatment step with a ligand, said at least one ligand is in liquid phase or in vapor phase; and, in the treatment step with an additive, said additive is in liquid phase or in vapor phase.

In an implementation of the method, the ligand is in vapor phase and during the treatment step with a ligand, said at least one ligand is mixed with at least one carrier gas belonging to the group comprising dinitrogen, helium and argon.

In an implementation of the method, said at least one ligand is at a partial pressure comprised between 0.1 mbar and 50 mbar. Preferably, said at least one ligand is at a partial pressure comprised between 14 mbar and 35 mbar.

In an implementation of the method, the treatment step with an additive, said at least one additive is in vapor phase and is mixed with at least one carrier gas belonging to the group comprising dinitrogen, helium and argon.

In an implementation of the method, said at least one additive is at a partial pressure comprised between 1 mbar and 900 mbar, more particularly between 200 mbar and 600 mbar, and preferably greater than 400 mbar.

In an implementation of the method, the method comprises an activation step in which open pores of the metal-organic framework are made accessible for the adsorption of molecules by a heat treatment carried out under dynamic vacuum, under a flow of inert gas, or by immersion in a solvent.

In an implementation of the method, the layer of metal oxide, before the implementation of the reaction cycles P, has a thickness greater than 18 nanometers and is composed of zinc oxide; the ligand used in the ligand treatment step is 2-methylimidazole; the additive used in the additive treatment step is water, the reaction cycle P is repeated at least fifteen times; and the activation step consists of a heat treatment up to 280° C. under dinitrogen.

According to an implementation of the method, the entire formation method does not implement any layer of metal-organic oxide other than the single metal-organic layer formed on the substrate.

Another aspect of the invention is a metal-organic framework formed by the implementation of such a method, the metal-organic framework formed on the substrate being in the form of a single monolithic layer having no strata. Preferably, this metal-organic framework has a thickness greater than 250 nm

### BRIEF DESCRIPTION OF THE DRAWINGS

Other aspects, aims, advantages and characteristics of the invention will appear better on reading the following detailed description of preferred embodiments thereof, given by way of non-limiting example, and made with reference to the appended drawings on which:

FIG. 1 illustrates the method according to the invention in which each reaction cycle comprises a treatment step with a ligand and a treatment step with an additive.

FIG. 2 illustrates an example of a method according to the invention in which at least one of the cycles of the plurality of reaction cycles comprises a purge step.

FIG. 3 illustrates the thickness of a porous metal-organic framework of ZIF-8 type obtained by an example of a method according to the invention as a function of the temperature of the substrate and as a function of the number of reaction cycles.

FIG. 4 illustrates the thickness of a porous metal-organic framework of ZIF-8 type obtained by an example of method according to the invention where, in the treatment step with a ligand, the ligand is in vapor phase at 100° C. and accompanied P1b, or not P1a, by a carrier gas, depending on the number of reaction cycles.

FIG. 5 illustrates an example of cycle A of a method for obtaining a layer of metal oxide from the forming step 20.

FIG. 6 illustrates a sectional view of a substrate covered with a layer of metal oxide gradually transforming into metal-organic framework during the successive implementation of the reaction cycles.

FIG. 7 illustrates the thickness of a ZIF-8 type metal-organic framework obtained as a function of the partial pressure of the additive, in this case water in vapor phase, during the implementation of a reaction cycle of the method according to the invention.

### DETAILED DESCRIPTION

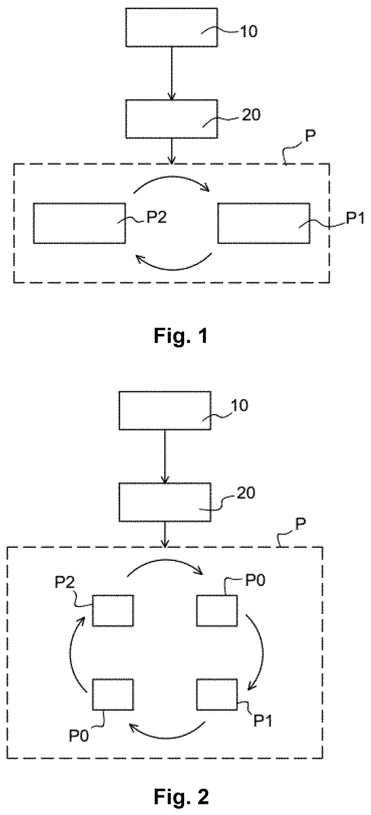

In the appended FIGS. 1 to 6 and in the remainder of the description, elements which are identical or similar in functional terms are identified by the same references.

In addition, the various elements are not represented to scale so as to favor the clarity of the figures to facilitate understanding.

Moreover, the different modes or examples and variants are not mutually exclusive and can, on the contrary, be combined with one another.

In the remainder of the description, unless otherwise indicated, the terms «substantially», «about», «overal» and «in the range of» mean «ithin 10%».

The invention relates firstly to a method for forming a metal-organic framework so as to form compounds known to those skilled in the art under the names ZIF-8, ZIF-72, ZIF-61, ZIF-67, ZIF-71, ZIF-94, MAF-6, MAF-28, MOF-5, H-KUST, UiO-66(-NH2) or Cu-TPA.

As illustrated in FIGS. 1 and 2, the method first of all comprises a step called for supplying a substrate 10. This substrate 10 has at least one deposition face. The substrate 10 can be flat or three-dimensional, the deposition face can therefore also be flat or three-dimensional. The substrate 10 can thus for example comprise pillars in particular in silicon, electromechanical systems in particular micrometric or nanometric or even be a quartz microbalance. The substrate 10 may comprise an insulator, a semiconductor, an electrical conductor, or a planar architecture combining these three elements such as a sensor or microprocessor circuit.

As illustrated in FIGS. 1, 2 and 5, the method also comprises a single so-called formation step 20 in which a single layer of metal oxide is formed on the deposition face, in other words on the substrate 10. This step can be implemented according to the general knowledge of the one skilled in the art. The terms «single layer» mean in an equivalent manner that the layer of metal oxide, itself potentially formed of a multitude of atomic sub-layers, during the formation step 20, is obtained only during this so-called formation step 20 and is no longer formed/deposited during the reaction cycles described below. This differs from classical methods involving porous metal-organic framework formation by reproducing cycles, where each cycle involves the formation of a new layer of metal oxide and an exposure to a ligand.

The advantage of depositing a single layer of metal oxide to obtain the entire metal-organic framework 5 is to be able to change the equipment after depositing the layer of metal oxide only once, which saves time. It is also further possible to chain all the steps of the method in the same equipment, which is all the more advantageous.

An additional advantage of the method, according to the invention, also lies in the formation of a metal-organic framework which can reach thicknesses greater than 250 nanometers. An additional advantage is that the metal-organic framework obtained is porous and crystallized. It therefore does not require any additional crystallization treatment, unlike methods using «Molecular Layer Deposition». An additional advantage is that the cost of the method is lower.

The layer of metal oxide is created from metal, for example in the form of a thin layer or particles based preferably on Zn, Co, Cu, Fe or even In. According to another embodiment, the oxide layer metal could be created from metal for example in the form of a Mn, Li, B, Cd, Hg, Pr, Mg, Al, Zr, Hf, Ti or even Ta-based thin layer or particles.

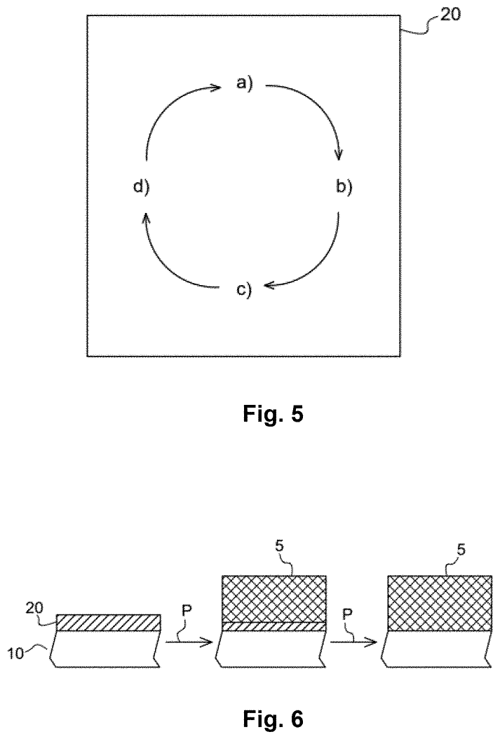

According to an embodiment example illustrated in FIG. 5, in the formation step 20, the layer of metal oxide is formed on the substrate 10 by the atomic layer deposition method. More specifically, in this example, to form the layer of metal oxide on the substrate 10, a first part of the method for obtaining the layer of metal oxide consists in carrying out a cycle «A» several times, under a pressure lower than one torr, to form atomic sub-layers which grow the layer of metal oxide. For this, an optional first step of cycle A consists in heating the substrate 10 between 30° C. and 360° C., preferably between 90° C. and 360° C. and more preferably still at about 150° C. This step allows to improve growth. Then, cycle A comprises a step a) of injecting a precursor. The precursor is for example an organometallic precursor or a halogenated precursor. For example, to obtain a zinc-based layer, the preferred organometallic precursor is diethylzinc, but other precursors are possible: dimethylzinc or zinc acetate or for halogenated precursors zinc dichloride (ZnCl₂). The injection of the precursor lasts between 1 ms and 30 minutes, preferably 25 ms. The cycle A comprises, following, a purge step b) to remove excess precursors or reaction by-products. The purge is carried out by placing under vacuum or by injecting an inert gas. At the end of the purge, the cycle A comprises a step c) of injecting a reactive agent such as water, ozone or even oxygen in the form of plasma. The injection of the reactive agent lasts between 1 ms and 30 minutes and preferably 25 ms. The injection of the reagent is possibly followed by a second purge d). This second purge allows to remove excess reagent or reaction by-products. To obtain, for example, ZnO, the organometallic precursor can be diethylzinc. For ZnO, the implementation of the cycle A is carried out about 300 times to obtain a layer of metal oxide of substantially 50 nanometers. Depending on the type of metal-organic framework to be obtained, the one skilled in the art will modify the nature of the layer of metal oxide, the precursor used and the number of cycles carried out.

The one skilled in the art can modify the formation parameters of the layer of metal oxide so that it can be dense, that is to say non-porous or, on the contrary, porous.

Other methods can be used by the one skilled in the art to obtain the layer of metal oxide such as, for example, vapor phase deposition (PVD, CVD) or else vaporization deposition, also called «spray-coating», or even by sol-gel technique.

In a variant embodiment, it is possible to provide for the substrate to comprise a tie layer forming the deposition face of the substrate 10. This tie layer is deposited prior to the cycle A. The tie layer makes it possible to avoid, later, the delamination of the metal-organic framework with respect to the substrate 10 in the event that the entire layer of metal oxide would be consumed.

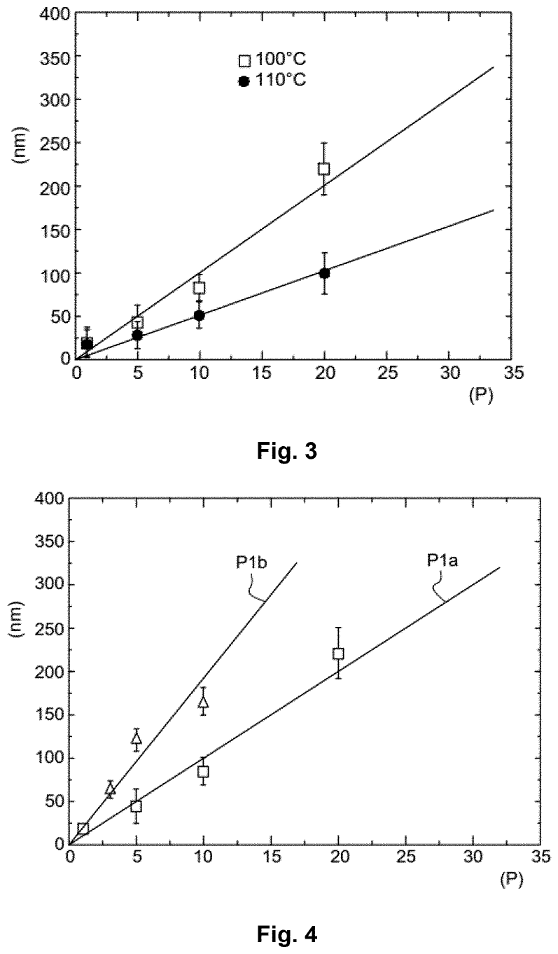

As illustrated in FIGS. 1, 2 and 6, the method further comprises a plurality of reaction cycles P. The reaction cycles P of the plurality are implemented successively. In other words, once the layer of metal oxide has been formed, the metal-organic framework is obtained in its entirety by implementing reaction cycles P, successively, without resorting to any other layer of metal oxide between the reaction cycles P. The layer of metal oxide is thus gradually transformed at each reaction cycle P into all or part of the metal-organic framework 5 to ultimately form the metal-organic framework 5. In other words, the method comprises at least two implementations of a reaction cycle P. Preferably, the reaction cycle P is implemented at least 15 times, for example 20 times (cf. FIG. 3). As long as the layer of metal oxide is not completely transformed into metal-organic framework, the reaction cycle P can be renewed, until the maximum yield is obtained by consuming the entire layer of metal oxide. In other words, the reaction cycle P can be repeated until the total consumption of the layer of metal oxide is reached. The thickness of the metal-organic framework increases with each iteration of the reaction cycle P. By the method of the invention, the successive parts of the metal-organic framework, which are formed progressively as the transformation of the layer of metal oxide at each iteration of the reaction cycle P, do not form strata without chemical interaction between them. At the end of the method, the different parts of the metal-organic framework are thus not distinct from each other and the metal-organic framework thus formed is monolithic without internal interfaces, that is to say without strata. The reaction cycle P must be carried out at least twice in succession. For example, in the case of obtaining ZIF-8, starting from a layer of metal oxide with a thickness substantially equal to 18 nanometers, a metal-organic framework of 250 nanometers thick is obtained. In conclusion, the element limiting the reaction taking place during the cycle P is the initial thickness of the layer of metal oxide. The greater the layer of metal oxide, the thicker a metal-organic framework layer can be obtained at the end of the method of the invention.

Advantageously, the metal-organic framework thus formed by the method of the invention consists of a monolithic layer, that is to say equivalently without strata containing metal oxide residues or without strata created by repeated steps of depositing layer of metal oxide on intermediate layers of metal-organic framework. The metal-organic framework obtained by the method of the invention is thus more homogeneous than that obtained by the aforementioned methods implementing cycles where each cycle involves the formation of a new layer of metal oxide on an intermediate layer of the metal-organic framework. In other words, the entire formation method does not implement any metal-organic oxide layer other than the single metal-organic layer formed on the substrate 10 in the formation step 20.

Each cycle comprises at least one treatment step with a ligand P1 in which at least one ligand is brought into contact with all or part of the layer of metal oxide. Thus, depending on the porosity or the nature of the layer of metal oxide, the ligand can react with the layer of metal oxide on the surface and/or in the thickness of the layer of metal oxide. The layer of metal oxide is then partially transformed, at each phase of the reaction P, into an additional portion of the metal-organic framework to be formed.

By way of examples, the porous metal-organic frameworks ZIF-8, ZIF-72, ZIF-61, MAF-6 and ZIF-94 can be obtained from zinc oxide as the layer of metal oxide and respectively from 2-methylimidazole, 4,5-dichloroimidazole, 1H-imidazole and 2-methylimidazole, 2-ethylimidazole and 4-methylimidazole-5-carbaldehyde ligands. To obtain a metal-organic framework MAF-28, a ligand such as 3-(2-Pyridyl)-5-(4-pyridyl)-1,2,4-triazole can be used. To form the metal-organic framework ZIF-71, the ligand 4,5-dichloroimidazole can also be used.

It results from what has been described above that the porous metal-organic framework ZIF-61 can be obtained from zinc oxide as layer of metal oxide and a mixture of 1H-imidazole and 2-methylimidazole. In addition, it is also possible to obtain porous metal-organic frameworks ZIF-60 and ZIF-62 from zinc oxide as the layer of metal oxide and a mixture of 1H-imidazole and 2-methylimidazole ligands.

Thus, it is possible that each reaction cycle comprises the use of several mixed ligands depending on the metal-organic framework 5 to be obtained. In other words, each reaction cycle can for example be such that the treatment step P1 is a treatment step with at least two ligands (i.e. two or more ligands) so that said at least two ligands are mixed in order to obtain the metal-organic framework 5.

A metal-organic framework ZIF-67 can also be obtained from Cobalt oxide CoOx and the ligand 2-methylimidazole.

A metal-organic framework can also be obtained from copper oxide CuO with fumaric acid as a ligand.

In all cases, the ligand can be introduced in liquid form or in vapor form. When said at least one ligand is in vapor form, it can for example be supplied at a partial pressure comprised between substantially 0.1 mbar and 50 mbar, in particular between 1 and 30 mbar and for a reaction time ranging from 0.1 seconds to 30 minutes and in particular for less than 10 minutes. A minimum partial pressure of 1.10⁻⁵ mbar can also be considered. To obtain ZIF-8, the ligand used is 2-methylimidazole, its partial pressure is 25 mbar at 150° and it is injected at each reaction cycle P with a reaction time of about 5 minutes.

Preferably, said at least one ligand in vapor phase (that is to say in vapor form) is at a partial pressure comprised between 14 mbar and 35 mbar.

The temperature of the substrate 10 as well as that of the layer of metal oxide and/or of the metal-organic framework being formed and/or of said at least one ligand during step P1 can be comprised and/or maintained at least at 20° C., preferably between 80° C. and 180° C. and in particular at about 100° C. or 110° C. The temperature of a reservoir in which the ligand is placed can be higher than in the reaction enclosure where the substrate 10 is placed. This makes it possible to promote the transport of the ligand and the absorption by the substrate and/or the oxide layer. In one example, the ligand reservoir is at a temperature between 140 and 160° C.

During the treatment step with a ligand P1, said at least one ligand can for example be mixed with at least one carrier gas. As illustrated in FIG. 4, in case P1b, a carrier gas such as nitrogen, helium or argon is used. The partial pressure of the carrier gas can be comprised between 0.1 mbar and 900 mbar and more particularly around 150 mbar.

The cycle P also comprises a so-called treatment step with an additive P2 in which at least one additive is in contact with the layer of metal oxide or with an additional portion of the metal-organic framework obtained at the end of the treatment step with the ligand P1.

In particular, the additive participates in the synthesis of the metal-organic framework 5. Thus the additive, within the meaning of the present description, is a reagent which ultimately promotes the transformation of all or part of the layer of metal oxide into metal-organic framework 5. In particular, the presence of the additive in the concerned reaction cycle P makes it possible to promote, in particular by forming OH groups, the transformation of metal oxide from the layer of metal oxide in order to form the metal-organic framework 5. This is particularly the case when the layer of metal oxide is made of ZnO and the metal-organic framework 5 to be formed is a ZIF such as ZIF-8 or other in particular depending on the used ligand. In particular, the presence of the additive allows the reaction (that is to say the transformation of the layer of metal oxide in whole or in part into metal-organic framework 5) to be cycled at the same growth rate at each cycle of the plurality of reaction cycles P.

Said additive is for example water or an alcohol such as ethanol, methanol, a diol or a polyol or a combination of these elements or else a product of a preceding reaction intended to form one of these elements in the reaction chamber. For example, in the context of the implementation of the method according to the invention to manufacture a ZIF-8, the additive used is water.

The additive can be in vapor or liquid form.

When the additive is in vapor form, it can be injected at a partial pressure comprised between, for example, 1 mbar and 900 mbar and more particularly between 200 and 600 mbar, preferably substantially equal to 400 mbar. The injection of the additive can last for a time comprised between 0.1 s and 30 minutes and in particular less than 5 minutes. The additive can also be mixed with at least one carrier gas such as nitrogen, helium or argon.

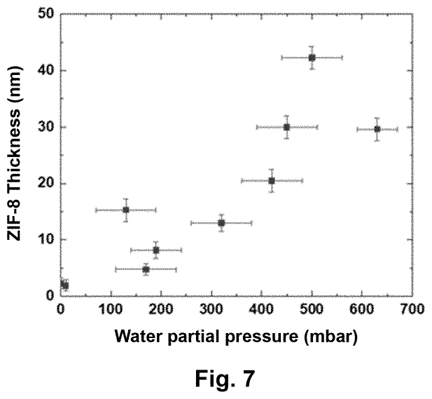

Preferably, while remaining compatible with the upper limits of the ranges given above, the partial pressure of the additive in vapor phase (that is to say in vapor form) is greater than 400 mbar. In particular, FIG. 7 shows what it is possible to obtain as thickness in nanometers for metal-organic ZIF-8 frameworks according to the partial pressure in mbar of the additive used then formed by water under vapor form. In the case of this FIG. 7, the layer of metal oxide formed on the substrate 10 is a layer of ZnO having a thickness of 50 nm, this layer of metal oxide being treated within the framework of the results of FIG. 7 by implementing, for different partial pressures of the additive, a single vapor phase cycle with 2-methylimidazole as ligand and with water as additive; this vapor phase cycle therefore groups together the step of treatment with the ligand and the treatment step with the additive and this cycle in vapor phase is in the present case carried out at about 103° C. This FIG. 7 shows that, in order to obtain a metal-organic framework ZIF-8 thickness greater than 20 nm per reaction cycle, it is preferable that the partial pressure of the additive be greater than 400 mbar. Indeed, reading FIG. 7 makes it possible to deduce that the thicknesses of the metal-organic frameworks 5 are greater between 400 mbar and 600 mbar of partial pressure for the additive when the additive is water in vapor form. FIG. 7 makes it possible to determine the thicknesses of metal-organic frameworks ZIF-8 which can be reached during the implementation of the first reaction cycle of the plurality of reaction cycles P, while knowing that of course, within the framework of the formation method as described, one or more other cycles identical to this first cycle follow this first cycle in order to increase the thickness of the metal-organic framework 5 in particular from cycle to cycle. Of course, this manipulation was carried out for the ZIF-8, but can be generalized to any other ZIF.

The temperature of the substrate 10 and/or of the additive during this step can be comprised and/or maintained between 80° C. and 180° C. and in particular at 100° C. or 110° C. Generally, the temperature of the substrate is not modified between the steps of treatment with a ligand P1 and the treatment step with an additive P2.

FIGS. 3 and 4 further show that the obtained metal-organic framework thickness is substantially proportional to the number of times the cycle P is implemented. It is noticed an increase in the thickness according to the number of cycles which evolves in a first approximation in a linear way and without apparently reaching a plateau. This indicates that carrying out additional cycles would make it possible to obtain even greater thicknesses, which is unprecedented for gas-based synthesis.

More particularly, FIG. 3 shows that a substrate temperature of 100° C. allows obtaining a thicker metal-organic framework than for 110° C.

FIG. 4 also shows that when the ligand is accompanied by a carrier gas like case P1b, this makes it possible to obtain a greater thickness of the metal-organic framework than without a carrier gas like case Pia. Thus, after 20 cycles, the thickness of the metal-organic framework can exceed 250 nanometers, which is advantageous for increasing the efficiency of the metal-organic framework once formed in the detection devices or for better filtering gases, for example.

It is possible to generate or modify a porosity or a hydrophobic character of the metal-organic framework by changing the nature of the layer of metal oxide and/or of the ligand and/or of the additive as well as their respective partial pressures. As illustrated in FIG. 2, according to an implementation variant of the method, at least one of the cycles of the plurality of reaction cycles P comprises at least one purge step P0. This purge step P0 can consist of placing it under vacuum or supplying inert gas. The purge step P0 is performed before and/or after the treatment step with a ligand P1. One hypothesis is that this makes it possible in particular to interact with the pores of the metal-organic framework created in previous cycles, for example to empty them of products, such as oxidants, that have not reacted before.

The purge step P0 can last between a few seconds and 30 minutes and in particular 10 minutes.

The placing under vacuum and/or the supply of inert gas applies to at least one of the additional portions of the metal-organic framework obtained in the step of treatment with a ligand P1 of each reaction cycle P or to the layer of metal oxide or equivalently its remaining portion.

In an implementation of the method, the step of treatment with an additive P2 is sequentially done. According to a variant embodiment, the treatment step with an additive P2 takes place at least in part during the treatment step with a ligand P1.

The repetition of the cycle P has the surprising effect of increasing the thickness of the metal-organic framework, without any intermediate addition of a layer of metal oxide. This is advantageous because unlike methods where a layer of metal oxide is deposited at each cycle, a remaining portion of the layer of metal oxide does not block the passage of reagents such as the ligand and/or the additive towards the part of the unreacted layer of metal oxide.

In an implementation of the method, the reaction cycles P are repeated until the layer of metal oxide is completely transformed into metal-organic framework. This advantageously makes it possible to obtain a metal-organic framework having a thickness greater than 250 nanometers.

In a particular implementation of the manufacturing method of the metal-organic framework, an activation step occurring at the end of the method, makes it possible to eliminate the potential residues in the pores of the formed metal-organic framework. This has the advantage of being able to carry out the adsorption of molecules in the open porosity of the framework. This activation step consists of heating the assembly consisting of the substrate and the metal-organic framework under vacuum or under an inert atmosphere at temperatures comprised between 50 and 300° C., or else immersing it in a solvent, such as methanol, at a temperature between room temperature and the boiling point.

An advantage of the activation step and/or of the purge steps is that the possible passage of a gas or a liquid through the pores of the metal-organic framework is improved to reach the part of the layer metal oxide that has not yet been transformed into part of the metal-organic framework.

The method can be applied for example for the integration of the metal-organic framework in gas detection or pre-concentration devices, in nano/micrometric electromechanical systems called NEMS or MEMS, in air purifiers, in gas separation membranes and dielectric thin films. It is also possible to use this method in the manufacture of processors or sensors.

Another aspect of the invention is the metal-organic framework 5 formed by the application of such a method from a single layer of metal oxide obtained on the substrate 10. The metal-organic framework 5 thus formed is consisting of a single monolithic metal-organic layer and not of a plurality of intermediate layers with few chemical bonds between them and showing the presence of multiple weakened interfaces as could be the case for methods implementing a new layer of metal oxide at each cycle.

In an example, the monolithic layer composing the metal-organic framework is supplemented by the remaining portion of the layer of metal oxide which has not been consumed. This differs from methods where a metal oxide deposit is made at each cycle since in these methods there can be as many remaining portions of layer of metal oxides as there are number of cycles.

In an example, it is possible to obtain a metal-organic framework having a thickness greater than 250 nanometers. Such a thickness does not seem to be obtainable by other methods known to one skilled in the art using gases according to microelectronics methods. Indeed, the other methods do not carry out a step of treatment with a ligand then a treatment with an additive P2 in a cyclic manner, that is to say repeatedly and successively without adding a layer of metal oxide between each reaction cycle. Such a step makes it possible to interact with the pores and the surface of the metal-organic framework and/or with the portion of the remaining layer of metal oxide to promote the growth of the metal-organic framework.

Thus, the metal-organic framework 5 can be formed by implementing the formation method as described previously so that the metal-organic framework 5 formed on the substrate 10 is in the form of a single monolithic layer having no strata, this metal-organic framework 5 having a thickness greater than 250 nm and, for example, less than 5 μm.

1. A method for forming a metal-organic framework comprising:
a step of supplying a substrate;
a single step of forming a single layer of metal oxide formed on the substrate, said layer of metal oxide being transformed in whole or in part into metal-organic framework by successive implementation of a plurality of reaction cycles;
each reaction cycle of the plurality of reaction cycles comprising:
a treatment step with at least one ligand;
a treatment step with at least one additive;
the reaction cycles being implemented at least twice so as to form the metal-organic framework on the substrate.

2. The method for forming a metal-organic framework according to claim 1, wherein the reaction cycle comprises a purge step consisting of placing under vacuum and/or supplying inert gas; the purge step being carried out before and/or after the treatment step with a ligand.

3. The method for forming a metal-organic framework according to claim 1, wherein the treatment step with an additive takes place at least in part during the treatment step with a ligand.

4. The method for forming a metal-organic framework according to claim 1, wherein the metal oxide is a zinc oxide, a cobalt oxide, a copper oxide, an iron oxide or an indium oxide.

5. The method for forming a metal-organic framework according to claim 1, wherein the reaction cycles are repeated until the layer of metal oxide is completely transformed into metal-organic framework.

6. The method for forming a metal-organic framework according to claim 1, wherein the additive is water or an alcohol or a polyol or a combination of these additives or a reagent intended to form at least one of these additives during the reaction cycle.

7. The method for forming a metal-organic framework according to claim 1, wherein the substrate and/or said ligand and/or said additive is maintained at a temperature comprised between 80° C. and 180° C. during the reaction cycle.

8. The method for forming a metal-organic framework according to claim 1, wherein, in the treatment step with a ligand, said at least one ligand is in liquid phase or in vapor phase;
and wherein, in the treatment step with an additive, said additive is in liquid phase or in vapor phase.

9. The method for forming a metal-organic framework according to claim 8, wherein the ligand is in vapor phase and during the treatment step with a ligand, said at least one ligand is mixed with at least one carrier gas belonging to the group comprising dinitrogen, helium and argon.

10. The method for forming a metal-organic framework according to claim 9, wherein said at least one ligand is at a partial pressure comprised between 0.1 mbar and 50 mbar, preferably between 14 mbar and 35 mbar.

11. The method for forming a metal-organic framework according to claim 8, wherein, in the treatment step with an additive, said at least one additive is in vapor phase and is mixed with at least one carrier gas belonging to the group comprising dinitrogen, helium and argon.

12. The method for forming a metal-organic framework according to claim 11, wherein said at least one additive is at a partial pressure comprised between 1 mbar and 900 mbar, more particularly between 200 mbar and 600 mbar, and, preferably, greater than 400 mbar.

13. The method for forming a metal-organic framework according to claim 1, wherein the method comprises an activation step in which open pores of the metal-organic framework are made accessible for adsorption of molecules by heat treatment carried out under dynamic vacuum, under a flow of inert gas, or by immersion in a solvent.

14. The method for forming a metal-organic framework according to claim 13, wherein the layer of metal oxide, before the implementation of the reaction cycles, has a thickness greater than 18 nanometers and is composed of zinc oxide; wherein the ligand used in the treatment step with a ligand is 2-methylimidazole; wherein the additive used in the treatment step with an additive is water, wherein the reaction cycle is repeated at least fifteen times; and wherein the activation step consists of a heat treatment up to 280° C. under dinitrogen.

15. A metal-organic framework formed by implementing a method according to claim 1, the metal-organic framework formed on the substrate being in the form of a single monolithic layer with no strata.

16. The metal-organic framework, according to claim 15, wherein the metal-organic framework has a thickness greater than 250 nm.

17. The method for forming a metal-organic framework according to claim 2, wherein the treatment step with an additive takes place at least in part during the treatment step with a ligand.

18. The method for forming a metal-organic framework according to claim 17, wherein the metal oxide is a zinc oxide, a cobalt oxide, a copper oxide, an iron oxide or an indium oxide.

19. The method for forming a metal-organic framework according to claim 18, wherein the reaction cycles are repeated until the layer of metal oxide is completely transformed into metal-organic framework.

20. The method for forming a metal-organic framework according to claim 19, wherein the additive is water or an alcohol or a polyol or a combination of these additives or a reagent intended to form at least one of these additives during the reaction cycle.
